(19) United States
(12) Patent Application Publication
(10) Pub. No.: US 2013/0160367 A1
(43) Pub. Date: Jun. 27, 2013

(54) AIRFLOW WINDOW

(71) Applicant: LI-PING CHEN, Tu-Cheng (TW)

(72) Inventor: LI-PING CHEN, Tu-Cheng (TW)

(73) Assignee: HON HAI PRECISION INDUSTRY CO., LTD., Tu-Cheng (TW)

(21) Appl. No.: 13/591,867

(22) Filed: Aug. 22, 2012

(30) Foreign Application Priority Data
Dec. 22, 2011 (TW) 100147892

(51) Int. Cl. H05K 7/20; E06B 7/086

(52) U.S. Cl. 49/92.1

(57) ABSTRACT

An airflow window includes an outer frame, an inner frame, and shutters. The outer frame defines a first opening and a plurality of guiding slots. The inner frame defines a second opening. The first opening communicates with the second opening. Each shutter includes an interfering tab. The shutters cooperatively block the first opening and the second opening in a closed state. A surface in each guiding slot retards a moving speed of the shutters on the interfering tab when the shutters rotate from an open state to the closed state.

### CROSS-REFERENCE TO RELATED APPLICATIONS

This application claims all benefits accruing under 35 U.S.C. §119 from Taiwan Patent Application No. 100147892, filed on Dec. 22, 2011, in the Taiwan Intellectual Property Office, the contents of which are hereby incorporated by reference. Relevant subject matter is disclosed in co-pending U.S. Patent Applications entitled “AIRFLOW WINDOW”, Attorney Docket Number US41595, U.S. application Ser. No. 13/543014, filed on Jul. 6, 2012.

### BACKGROUND

1. Technical Field

The disclosure generally relates to airflow windows, especially to an airflow window of a computer system.

2. Description of Related Art

Computer systems may include fans for dissipating heat from a plurality of electronic elements. An airflow window may be needed to prevent output airflow from flowing back into the computer system affecting the dissipation of the electronic elements.

Airflow window may include many shutters. The shutters may make noise when the shutters are repeatedly opened and closed. Thus, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an airflow window in one embodiment.

FIG. 2 is an assembly view of an outer frame and an inner frame of the airflow window of FIG. 1.

FIG. 3 is an assembled view of the airflow window of FIG. 1.

FIG. 4 is similar to FIG. 3, but a plurality of shutters are rotated up and the view being shown from another aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

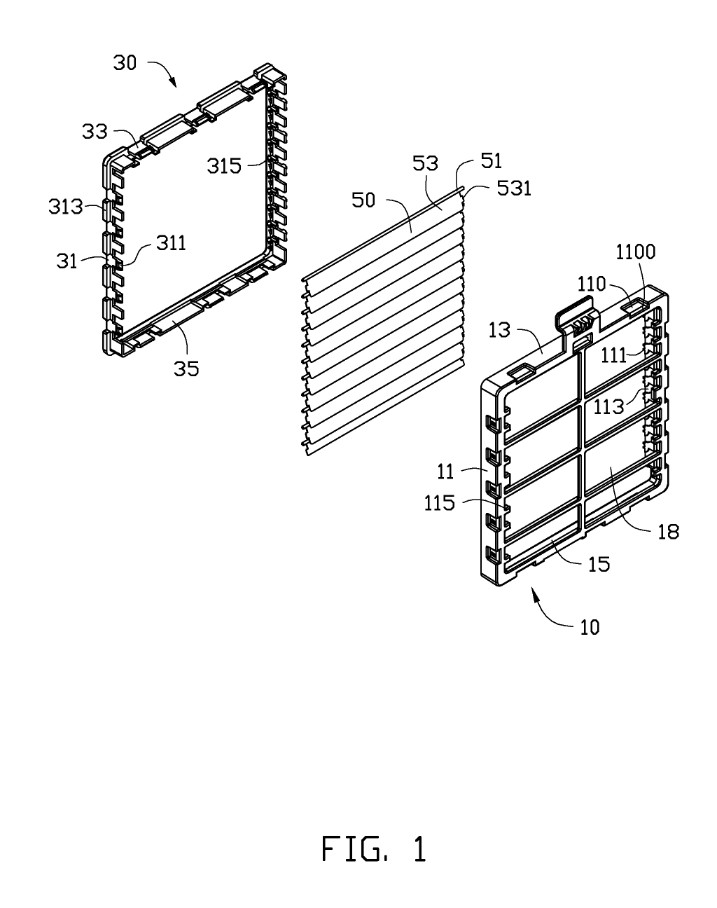

Referring to FIG. 1, in one embodiment, an airflow window includes an outer frame 10, an inner frame 30, and a plurality of shutters 50.

The outer frame 10 is substantially rectangular. The outer frame 10 includes two sidewalls 11, a top wall 13, and a bottom wall 15. The sidewalls 11 are substantially parallel. Three locking holes 110 are defined in the top wall 13. A restricting portion 1100 is located aside each locking hole 110. An opening 18 is defined by the sidewalls 11, the top wall 13, and the bottom wall 15. Each of the sidewalls 11 includes a plurality of first mounting portions 111 on an outer flange. A plurality of blocks 115 is located on the sidewalls 11. A plurality of guiding slots 113 are defined in an inner side of the sidewalls 11. Each of guiding slots 113 has an arcuate shape. Each of guiding slots 113 has a friction surface.

The inner frame 30 is substantially rectangular. The inner frame 30 includes a plurality of first resilient hooks 31, three second resilient hooks 33, a plurality of blocking ridges 313, and an engaging flange 35 corresponding to the bottom wall 15 of the outer frame 10. Each of the first hooks 31 includes a locking end 311. The inner frame 30 includes a plurality of second mounting portions 315.

Each shutter 50 includes a pivot portion 51 and a blade portion 53. The pivot portion 51 can be rolled from an end of each blade portion 53. A length of the pivot portion 51 is greater than a length of the blade portion 53. The blade portion 53 may comprises metal, such as iron. Each of the blade portions 53 includes two interfering tabs 531 at two lateral sides thereof. Each of the plurality of shutters 50 may be integrally formed.

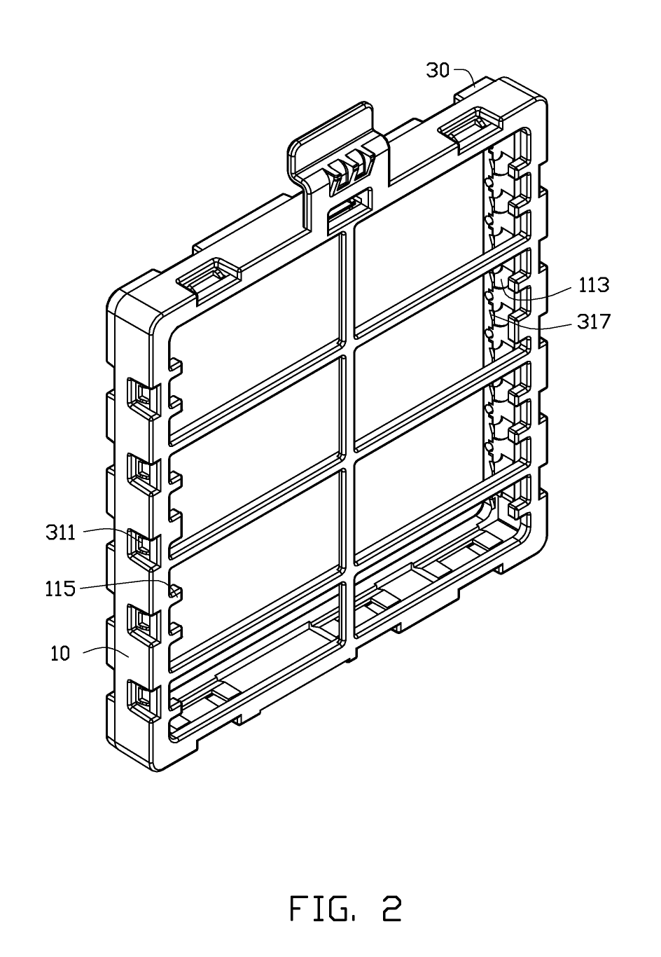

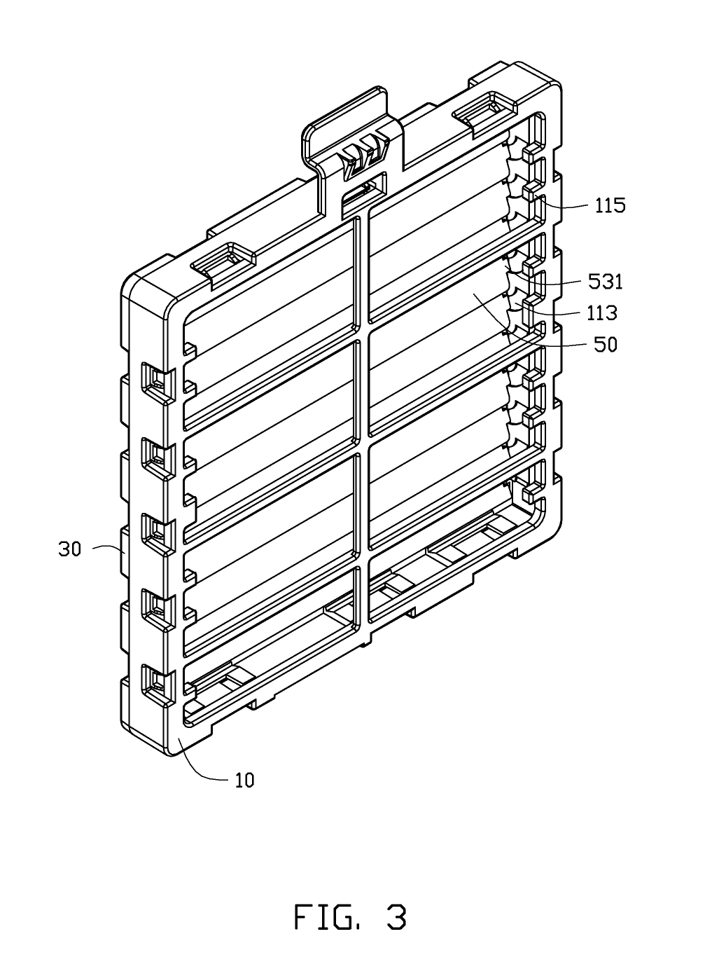

Referring to FIG. 2 and FIG. 3, in assembly, each pivot portions 51 is located in one of the second mounting portions 315 of the inner frame 30. The inner frame 30 with the plurality of shutters 50 is attached to the outer frame 10. The engaging flange 35 is located on an inner side of the bottom wall 15 of the outer frame 10. The plurality of first resilient hooks 31 are engaged with sidewalls 11 of the outer frame 10. The second resilient hooks 33 are engaged with the locking holes 110 of the top wall 13 of the outer frame 10. The restricting portions 1100 restrict further movement of the second resilient hooks 33. The inner frame 30 abuts the blocks 115 of the outer frame 10. The blocking ridges 313 abut the outer flange of the outer frame 10. The pivot portions 51 are engaged between the plurality of first mounting portions 111 and the plurality of second mounting portions 315. Each of the plurality of pivot portions 51 extends along a first direction, that is substantially perpendicular to the sidewalls 11. The interfering tabs 531 extend into the guiding slots 113 of the outer frame 10.

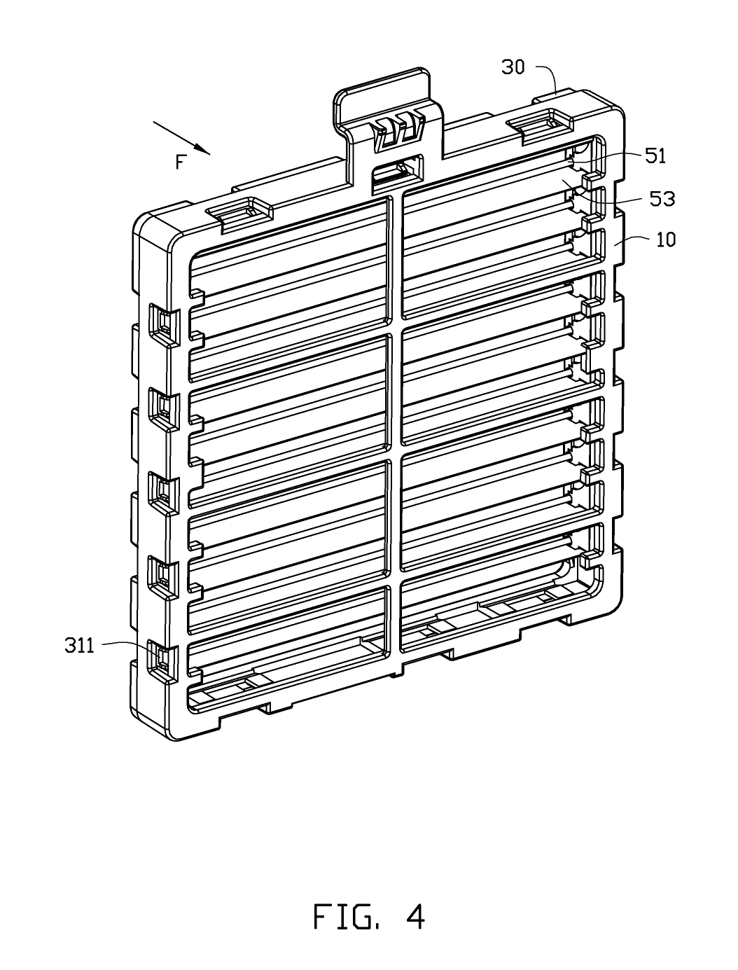

Referring also to FIG. 4, in use, the airflow window can be opened along an one way direction by airflow F. In a closed state, the plurality of shutters 50 fall down naturally and shut the opening 18 of the outer frame 10. When the airflow F extends towards the plurality of shutters 50, the plurality of shutters 50 are blown upward and rotated to an open state. The surface of the guiding slots 113 rub the interfering tabs 531 of each blade portion 53 to reduce the rotating speed of the shutter 50. In the open state, the plurality of shutters 50 are rotated at a maximum angle. When releasing the plurality of shutters 50, the airflow F stops, the guiding slots 113 can reduce a rotating speed of the plurality of shutters 50 when the plurality of shutters 50 rotates to the closed state or to a maximum angle from the desire angle. A crash speed of the plurality of shutters 50 to the outer frame 10 is also reduced. Thus, noise generated by the plurality of shutters 50 is reduced.

It is also understood, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An airflow window comprising:
an outer frame defining a first opening and a plurality of guiding slots;
an inner frame defining a second opening, and the first opening communicating with the second opening;
a plurality of shutters, each of the plurality of shutters comprising an interfering tab, the plurality of shutters being adapted to cooperatively block the first opening and the second opening in a closed state; and
wherein a surface in each of the plurality of guiding slots retards a moving speed of the plurality of shutters on the interfering tab when the plurality of shutters rotate from an open state to the closed state.

2. The airflow window of claim 1, wherein the outer frame comprises two substantially parallel sidewalls, each of the plurality of shutters comprises a pivot portion, and the pivot portion extends along a first direction that is substantially perpendicular to the substantially parallel sidewalls.

3. The airflow window of claim 2, wherein the pivot portion is retained cooperatively by the outer frame and the inner frame.

4. The airflow window of claim 1, wherein the inner frame comprises a plurality of resilient hooks, and the outer frame comprises a plurality of locking holes corresponding to the plurality of resilient hooks.

5. The airflow window of claim 1, wherein the interfering tab protrudes at a lateral side of each of the plurality of shutters.

6. The airflow window of claim 1, wherein each of the plurality of shutters is integral formed.

7. The airflow window of claim 1, wherein each of the plurality of guiding slots is arcuate.

8. An airflow window comprising:
an outer frame;
an inner frame engaged with the outer frame; and
a plurality of shutters being pivotably retained cooperatively by the inner frame and the outer frame,
wherein each of the plurality of shutters is interfered with the outer frame to reduce a rotating speed of the plurality of shutters when each of the plurality of shutters rotates up or down.

9. The airflow window of claim 8, wherein the outer frame comprises two substantially parallel sidewalls, each of the plurality of shutters comprises a pivot portion, and the pivot portion extends along a first direction that is substantially perpendicular to the substantially parallel sidewalls.

10. The airflow window of claim 8, wherein the outer frame defines a plurality of guiding slots, and each of plurality of shutters comprises an interfering tab extending into each of the plurality of guiding slots.

11. The airflow window of claim 10, wherein the interfering tab protrudes at a lateral side of each of the plurality of shutters.

12. The airflow window of claim 10, wherein each of the plurality of guiding slots is arcuate.

13. The airflow window of claim 8, wherein the inner frame comprises a plurality of resilient hooks, and the outer frame comprises a plurality of locking holes corresponding to the plurality of resilient hooks.

14. The airflow window of claim 8, wherein each of the plurality of shutters is integral formed.

15. An airflow window comprising:
an outer frame, defining at least one guiding slots;
an inner frame engaged with the outer frame; and
a plurality of shutters being pivotably retained between the inner frame and the outer frame, and each of the plurality of shutter comprising an interfering tab,
wherein each of the plurality of shutters is rotated from an open state, where the interfering tab is located at a bottom end of the at least one guiding slot, to a closed state, where the interfering tab is located at a top end of the at least one guiding slot.

16. The airflow window of claim 15 wherein the outer frame comprises two substantially parallel sidewalls, each of the plurality of shutters comprises a pivot portion, and the pivot portions extends along a first direction that is substantially perpendicular to the substantially parallel sidewalls.

17. The airflow window of claim 15, wherein the interfering tab protrudes at a lateral side of each of the plurality of shutters.

18. The airflow window of claim 15, wherein the at least one guiding slot is arcuate.

19. The airflow window of claim 15, wherein the inner frame comprises a plurality of resilient hooks, and the outer frame comprises a plurality of locking holes corresponding to the plurality of resilient hooks.

20. The airflow window of claim 15, wherein each of the plurality of shutters is integral formed.
